(19) United States
(12) Patent Application Publication
(10) Pub. No.: US 2014/0087515 A1
(43) Pub. Date: Mar. 27, 2014

(54) METHOD FOR THE CONTACT SEPARATION OF ELECTRICALLY-CONDUCTING LAYERS ON THE BACK CONTACTS OF SOLAR CELLS AND CORRESPONDING SOLAR CELL

(71) Applicant: Institut Für Solarenergieforschung GmbH, Emmerthal (DE)

(72) Inventors: Andreas Teppe, Alzenau (DE); Peter Engelhart, Hameln (DE); Jörg Müller, Sandersdorf (DE)

(73) Assignee: Institut Für Solarenergieforschung GmbH, Emmerthal (DE)

(21) Appl. No.: 14/090,739

(22) Filed: Nov. 26, 2013

Related U.S. Application Data
(62) Division of application No. 12/881,714, filed on Sep. 14, 2010, now abandoned.
Application No. 12/881,714 is a division of application No. 11/665,318, filed on Apr. 13, 2007, now abandoned.

(30) Foreign Application Priority Data
Oct. 14, 2004 (DE) 10 2004 050 269.2

(51) Int. Cl. H01L 31/18; H01L 31/0224

(52) U.S. Cl. CPC H01L 31/18; H01L 31/022458
USPC 438/98

(57) ABSTRACT

A method for fabricating a solar cell including a semiconductor substrate is proposed where electrical contacting is made on the back side of the semiconductor substrate. The back side of the semiconductor substrate has locally doped regions. The adjacent regions exhibit different doping from the region. The two regions are initially coated with electrically conductive material over the entire area. So that the conductive material does not short-circuit the solar cell, the two regions are covered with a thin electrically insulating layer at least at the region boundaries. The electrically conductive layer is separated by applying an etch barrier layer over the entire surface which is then removed free from masking and selectively e.g. by laser ablation, locally above the insulating layer. The conductive layer is locally removed in the area of the openings of the etch barrier layer by subsequent action of an etching solution.

### CROSS-REFERENCE TO RELATED APPLICATIONS

The present application is a divisional of U.S. patent application Ser. No. 12/881,714, filed on Sep. 14, 2010, which application is a divisional of U.S. patent application Ser. No. 11/665,318 filed Apr. 13, 2007, which is a national phase entry under 35 U.S.C. §371 of International Application No. PCT/EP05/11046 filed Oct. 13, 2005, published in English as WO/2006/042698, which claims priority from DE102004050269.2 filed Oct. 14, 2004, all of which are incorporated herein by reference.

### BACKGROUND OF THE INVENTION

The present invention relates to a solar cell in which both an emitter contact and a base contact are arranged on a back side of a semiconductor substrate and a method for fabricating such a solar cell. In particular, the invention relates to a method for electrically separating base and emitter contacts arranged on the back side of a solar cell.

Solar cells are used to convert light into electrical energy. In this case, charge carrier pairs generated by light in a semiconductor substrate are separated by a pn junction and then supplied via the emitter contact and the base contact to a power circuit comprising a consumer.

In conventional solar cells, the emitter contact is mostly arranged on the front side, i.e. on the side facing the light source, of the semiconductor substrate. However, solar cells have also been proposed, for example, in JP 5-75149 A, DE 41 43 083 and DE 101 42 481 in which both the base contact and also the emitter contact are arranged on the back side of the substrate. Firstly, this avoids shading of the front side by the contacts, leading to enhanced efficiency and improved aesthetics of the solar cell, and secondly, these solar cells are easier to connect in series since the back side of a cell need not be electrically connected to the front side of a neighbouring cell.

In other words, a solar cell without front-side metallisation has a plurality of advantages: the front side of the solar cell is not shaded by any contact so that the incident radiation energy can generate charge carriers in the semiconductor substrate without restriction. In addition, these cells can be easier to connect to modules and they have good aesthetics.

However, conventional so-called back-contact solar cells have several disadvantages. Their fabrication methods are mostly elaborate. Some methods require a plurality of masking steps, a plurality of etching steps and/or a plurality of vapour deposition steps to form the base contact electrically separate from the emitter contact on the back side of the semiconductor substrate. Furthermore, conventional back-contact solar cells frequently suffer from local short circuits, caused for example by inversion layers between the base and the emitter region or by inadequate electrical insulation between the emitter and the base contact, leading to a reduced efficiency of the solar cell.

A solar cell without front-side metallisation is known, for example, from R. M. Swanson “Point Contact Silicon Solar Cells,” Electric Power Research Institute Rep. AP-2859, May 1983. This cell concept has been continuously further developed (R. A. Sinton “Bilevel contact solar cells,” U.S. Pat. No. 5,053,083, 1991). A simplified version of this point contact solar cell is being manufactured by SunPowerCorporation in a pilot line (K. R. McInthosh, M. J. Cudzinovic, D-D Smith, W-P. Mulligan and R. M. Swanson “The choice of silicon wafer for the production of low-cost rear-contact solar cells,” 3rd World Conference on PV Energy Conversion, Osaka 2003, in press).

For the fabrication of these solar cells, differently doped regions must be produced adjacent to one another in a plurality of masking steps and metallised or contacted by applying a partially multilayer metal structure.

A disadvantage here is these methods require a plurality of aligning masking steps and are therefore elaborate.

Known from JP 575149 A is a solar cell without front-side metallisation which has elevated and recessed regions on the back side of the solar cell. This solar cell can also only be fabricated using a plurality of masking and etching steps. In addition, the formation of elevated and recessed regions requires additional work steps compared to a solar cell with flat surfaces.

Patent DE 41 43 083 describes a solar cell without front-side metallisation in which aligning masking steps are not absolutely necessary. However, the efficiency of this cell is low since the inversion layer connects two contact systems which brings about a low parallel resistance and therefore a low fill factor.

Patent DE 101 42 481 describes a solar cell with base and emitter contacts on the rear side. This solar cell also has a rear-side structure but the contacts are located on the flanks of the elevations. This requires two vacuum vapour deposition steps to fabricate the contacts. In addition, the fabrication of a local emitter is technologically demanding in this cell.

A particular difficulty with back-contacted solar cells is the elaborate fabrication of the back side contacts where electrical short circuits must be absolutely avoided.

### BRIEF SUMMARY OF THE INVENTION

There may be a need to avoid or at least reduce the aforesaid problems and to provide a solar cell and a method of fabrication for a solar cell which achieves a high efficiency and is easy to produce.

The need may be achieved by a method of fabrication and a solar cell according to the invention.

In particular, the disclosed method and embodiments solve the problem of fabricating the two back-side contact systems i.e. base contact and emitter contact and their problem-free electrical separation in a simple manner and describes a solar cell which can be fabricated simply by this method.

According to a first aspect of the invention, a method for fabricating a solar cell is provided, comprising the following steps: providing a semiconductor substrate with a substrate front side and a substrate back side; forming an emitter region and a base region each on the substrate back side; forming an electrically insulating layer on the substrate back side at least in junction regions above a region boundary at which the emitter region adjoins the base region; depositing a metal layer at least on partial regions of the substrate back side; depositing an etch barrier layer at least on partial regions of the metal layer, wherein the etch barrier layer is substantially resistant towards an etchant for etching the metal layer; locally removing the etch barrier layer at least in partial regions of the junction regions; etching the metal layer, wherein the metal layer is substantially removed in the partial regions in which the etch barrier layer is locally removed.

A silicon wafer can be used as the semiconductor substrate. The method is particularly suitable for the fabrication of back contact solar cells in which an emitter is formed both on the front and also on the back side of the solar cell (for example, so-called EWT (Emitter Wrap Through) solar cells). As a result of the short distance from a pn junction separating the charge carrier pairs, lower-quality silicon wafers, for example, made of multicrystalline silicon or Cz silicon, having a minority carrier diffusion length shorter than the thickness of the wafer, can be used in these solar cells.

Thin semiconductor layers applied to a carrier substrate having thicknesses in the range of a few micrometer can be used as the semiconductor substrate. The method according to the invention is particularly advantageous for the fabrication of thin-layer solar cells because, in contrast to some of the conventional methods specified in the introduction, no structuring of the substrate back side is required but the method can be applied to substrates with a flat back side.

The emitter region to be formed subsequently and the base region of the solar cell have different n-type or p-type dopings. The definition of the two regions can be effected, for example, by locally protecting the base layer from diffusion using a masking layer or by diffusion over the entire surface and subsequently locally etching away the resulting emitter or removing it by means of laser ablation. The two regions can be nested in one another in a comb-like fashion (“interdigitated”). This has the result that charge carrier pairs generated in the semiconductor substrate only have to travel short distances up to a pn junction and are then separated there and can be removed via the metallisations contacting the respective regions. Recombination and series resistance losses can thus be minimised. In this case, the emitter region and the base region do not need to occupy the same surface fractions on the entire back-side surface.

In the junction region above the region boundary at which the emitter region adjoins the base region, i.e. at that point where a pn-junction reaches the surface of the substrate back side, an electrically insulating layer is formed on the substrate back side. “Above” is to be understood here as adjoining the surface of the substrate back side. “Junction regions” are understood as those regions which are laterally adjacent to the region boundary, i.e. parallel to the substrate surface.

The electrically insulating layer can be a dielectric which surface passivates both the substrate surface located thereunder and in particular the exposed pn-junction and also prevents short circuits between the emitter region and the base region caused by a metal layer subsequently located thereover.

The insulating layer is preferably formed with silicon oxide and/or silicon nitride. This can be formed by means of any known method. For example, an oxide can be grown thermally on the silicon surface or a nitride can be deposited by means of a CVD method. In this case, it is important that the layer is electrically insulated as well as possible. Any pinholes can adversely affect the insulation properties of the layer. Thus, care should be taken to ensure that the layer is as compact as possible. Thermally grown oxides are usually more compact than deposited nitrides and may thus be preferable.

Since the insulating layer should only be formed in the junction regions, but interlying regions should not be covered by the layer for purposes of electrical contacting, the insulating layer can be selectively applied through a mask, where attention should be paid to the correct positioning in relation to the region boundary.

Alternatively, the insulating layer can be formed over the entire area on the back side of the substrate and then removed locally, for example, in lines or spots, by laser ablation or local etching for example.

In another alternative, a masking layer which has been formed before in-diffusion of the emitter region on the base region in order to protect it from diffusion, can remain on the substrate back side and then serve as an insulating layer. Since emitter dopants also diffuse laterally under the masking layer during diffusion, this layer subsequently covers the region boundary between the emitter and base region.

In the next process step, a metal layer is preferably deposited on the entire back side of the substrate. Masking, for example, by photolithography, of individual regions of the substrate back side is not required. Partial regions of the substrate back side, used for example for holding the substrate during the deposition, possibly remain free from the metal layer. Aluminium is preferably used for the metal layer.

After the metal layer has been deposited, an etch barrier layer is deposited on this, again at least in partial regions. The etch barrier layer thus covers the metall layer, at least in part. Preferably both the metal layer and the etch barrier layer located thereover substantially cover the entire substrate back side.

According to an aspect of the invention, the etch barrier layer is substantially resistant to an etchant used to etch the metal layer. This means that an etchant, for example, a liquid etching solution or a reactive gas which severely attacks the metal layer, does not or only slightly etches the etch barrier layer. For example, the etching rate of the etchant relative to the metal layer should be very much higher, for example, by a factor of ten, than that relative to the etch barrier layer.

Preferably conductive and, in particular, solderable metals such as silver or copper can be used for the etch barrier layer. The term “solderable” is understood here in that a conventional cable or a contact strip can be soldered onto the etch barrier layer and this can be used, for example, for connecting solar cells to one another. In this case, it should be possible to use simple, cost-effective soldering methods without using special solders or special tools such as are required to solder aluminium or titanium or compounds of such metals, for example. It should be possible to solder the etch barrier, for example, using conventional silver solder and conventional soldering irons.

However, dielectrics such as silicon oxide (e.g. SiO2) or silicon nitride (e.g. Si3N4) can also be used and can possibly be used in subsequent fabrication steps for contacting the metal layer located thereunder.

The metal layer and/or the etch barrier layer are preferably deposited by vapour deposition or sputtering. Therein, both layers can by deposited during a single vacuum step.

The etch barrier layer is then removed locally at least in partial regions above the junction regions. In other words, the etch barrier layer is removed at least in part, where the substrate back side is covered by the electrically insulating layer at the region boundary of exposed pn junctions.

The etch barrier layer can preferably be removed free from masking, i.e. using no mask which has been laid on or generated photolithographically to locally open the etch barrier layer.

The etch barrier layer can preferably be locally removed by means of a laser by laser ablation. In this case, the etch barrier layer is locally vaporised by a high-energy laser or made to spall so that the metal layer located thereunder is exposed.

Alternatively, the etch barrier layer can be removed by means of an etching solution which is applied locally for example, by a dispenser similar to an ink jet printer.

In another alternative, the etch barrier layer can also be removed locally by mechanical means, for example, by scoring or sawing.

In a subsequent process step, the back side of the substrate with the metal layer located thereon and the etch barrier layer covering this, is exposed to an etchant. In the regions covered by the etch barrier layer the metal layer is not attacked or barely attacked by the etchant. In the partial regions where the etch barrier layer has been locally removed however, the etchant can directly attack the metal layer. The metal layer located under the etch barrier layer is etched away in these partial regions. A separating trench is formed, which extends as far as the electrically insulating layer located thereunder. As a result, the metal layer in the base region is no longer electrically connected to the metal layer in the emitter region.

A method according to the invention can achieve electrical insulation of the base contact from the emitter contact also located on the back side of the substrate in a simple manner. In this context, it is advantageous that the electrically insulating layer must cover the region boundary at all points but can also extend over substantially further regions of the substrate back side. A dielectric acting as an insulating layer can surface-passivate broad areas of the back surface of the substrate and must only be locally opened for contacting the emitter. The base contacts can be driven through the dielectric into the base region by an LFC method (laser fired contacts). Alternatively, the dielectric can be selectively locally opened prior to the metal deposition in the base region.

The local removal of the etch barrier layer must again lie merely somewhere in the area of the underlying junction regions and take place such that after the etching step, the entire base contact is completely electrically separated from the emitter contact. This means that the separating trenches insulating the emitter contact from the base contact should always run in regions in which the adjoining metal layers are insulated from the substrate back side by the underlying insulating layer. If broad areas of the substrate back side are covered by the insulating layer, this therefore provides great freedom with regard to the geometrical profile of the separating trench. It need not be aligned precisely above the region boundary of the surface-pn-junctions but can run laterally spaced apart from this region boundary. For example, the separating trench can be formed as meander-shaped. It can also be formed in such a manner that elongated metallisation finger regions insulated from one another by the separating trench taper from one side edge of the solar cell towards an opposite side edge.

According to a second aspect of the present invention, a solar cell is proposed, comprising: a semiconductor substrate comprising a substrate front side and a substrate back side; a base region of a first doping type on the substrate back side and an emitter region of a second doping type on the substrate back side; a dielectric layer in the junction regions above a region boundary at which the base region adjoins the emitter region; a base contact which electrically contacts the base region at least in partial regions and an emitter contact which electrically contacts the emitter region at least in partial regions, wherein the base contact and the emitter contact each have a metal layer in contact with the semiconductor substrate, wherein the metal layer of the base contact is laterally spaced apart from the metal layer of the emitter contact above the dielectric layer by a separating gap so that the emitter contact and the base contact are electrically separated.

In particular, the solar cell can have the features such as those formed by the method according to the invention described above.

In one embodiment, the solar cell is configured in such a manner that the metal layer of the base contact and the metal layer of the emitter contact are arranged substantially at the same distance from the substrate front side. In other words, this means that the two contacts are applied to a flat substrate back side. The contacts are therefore only separated laterally by a separating gap and there is no vertical spacing such as can be found in many conventional back-contact solar cells.

In a further embodiment, another thin metal layer is located above the metal layer forming the contacts, this thin layer serving as an etch barrier layer during the fabrication of the solar cell. This layer is preferably formed using a solderable material such as, for example, silver or copper. The contacts whose metal layer can be made of difficult-to-solder aluminium can be easily soldered with the aid of this layer and the solar cells thus interconnected to one another.

Further features and advantages of the invention are obtained from the following detailed description of preferred embodiments in connection with the accompanying drawings.

### BRIEF DESCRIPTION OF THE DRAWINGS

FIG. 1 shows a schematic sectional view of a solar cell according to the invention according to a first embodiment.

FIG. 2A to 2C schematically illustrate process steps of a process sequence according to the invention.

FIG. 3 shows a schematic sectional view of a solar cell according to the invention according to a second embodiment with separating trenches which are laterally offset with respect to a region boundary.

FIG. 4 shows a schematic view of a solar cell according to the invention according to a third embodiment in which the separating trench has a meander-shaped configuration.

FIG. 5 shows a schematic view of a solar cell according to the invention according to a fourth embodiment with tapering contact fingers.

### DETAILED DESCRIPTION

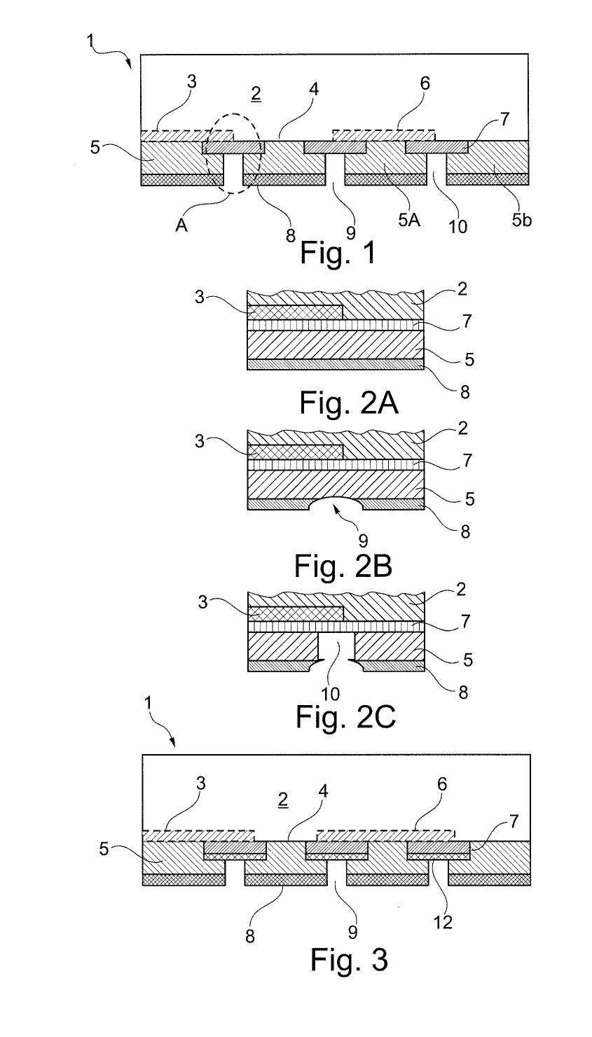

Embodiments of the solar cells 1 according to the invention and a method according to the invention suitable for their fabrication are now described with reference to FIGS. 1, 2A to 2C and 3. FIGS. 2A to 2C illustrate the process steps for separating back-contact regions with reference to region A bordered by the dashed line in FIG. 1.

On the back side of a p-doped silicon wafer serving as a semiconductor substrate 2, n-doped emitter regions 3 are diffused-in locally. For this purpose, the surface of the substrate 2 where no diffusion is to take place, is protected with a diffusion barrier, for example, silicon nitride and the substrate is then subjected to phosphorus diffusion.

An electrically insulating layer 7 in the form of a thermally grown silicon oxide layer and a silicon nitride layer deposited over this by CVD is then applied over the entire back side of the substrate. This layer 7 is then removed locally in strips by laser ablation in the area of the subsequent emitter contacting, i.e. over the emitter region 3. Then an aluminium layer serving as a metal layer 5 is initially deposited over the entire substrate back side, making direct contact with the back side of the substrate in the emitter region 3 whereas in the base region 4 and in a junction region adjacent to the region boundary 6, said layer is located above the insulating layer 7. In the same vapour deposition step, a silver layer serving as an etch barrier layer 8 is applied over the metal layer 5. A sequence of layers as shown in FIG. 2A is now provided.

Next, in a process step shown in FIG. 2B, the etch barrier layer 8 is locally opened using a laser. The geometry of the opened region 9 in which the etch barrier layer 8 is removed can be widely varied here. In order to prevent short circuits between the subsequent emitter contact and the subsequent base contact, it is merely necessary to ensure that the opened region 9 is already located above the insulating layer 7 and that an opened region 9 is located above or adjacent to each region boundary 6.

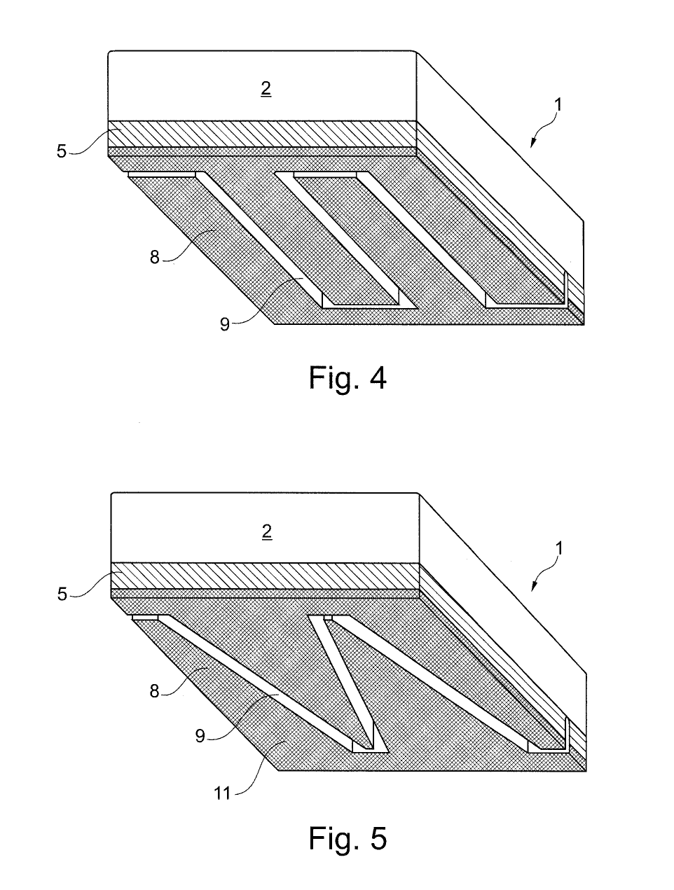

As can be seen in the embodiment illustrated in FIG. 4, the opened region 9 can have a meander-shaped profile. In this way, interdigitated contact fingers are formed. In another embodiment illustrated in FIG. 5, the interdigitated contact fingers are configured as tapered. This has the advantage that in regions of the contact fingers in which a high current flows, the cross-section of the contact fingers is large and thus resistance losses are reduced.

In a subsequent process step shown in FIG. 2C, the semiconductor substrate with the sequence of layers applied thereto is subjected to etching. In this case, a solution, for example, HCl-based or a reactive gas can be used as the etchant. This etchant does not attack or barely attacks the etching barrier. In the opened regions 9 however, the etchant acts directly on the metal layer 5 and etches it away. A separating trench 10 is formed, which extends down to the insulating layer 7 and separates the metal layer 5a of the emitter contact from the metal layer 5b of the base contact.

FIG. 3 shows an embodiment in which the separating trench 10 is located in a region laterally at a distance from the region boundary 6. Furthermore, a varnish layer 12 is applied locally over the insulating layer 7, increasing the resistance between the metal layer 5 and the underlying substrate. This can be particularly advantageous when the insulating layer 7 has microscopic pinholes which could cause short circuits.

To sum up and in other words, the invention can be described as follows: a solar cell (1) comprising a semiconductor substrate (2) is proposed where electrical contacting is made on the back side of the semiconductor substrate. The back side of the semiconductor substrate has locally doped regions (3). The adjacent regions (4) exhibit different doping from the region (3). The two regions (3, 4) are initially coated with electrically conductive material (5) over the entire area. So that the conductive material (5) does not short-circuit the solar cell, the two regions (3, 4) are covered with a thin electrically insulating layer (7), at least at the region boundaries (6).

The electrically conductive layer (5) is separated by applying an etch barrier layer (8) over the entire surface which is then removed free from masking and selectively e.g. by laser ablation, locally below the insulating layer (7). The conductive layer (5) is locally removed in the area of the openings (9) of the etch barrier layer (8) by subsequent action of an etching solution.

The following advantages are achieved among others with the solar cell which has been presented, also designated as HORIZON cell (HOrizontal Rear Interdigitated ZONes):

Base and emitter back contacts electrically insulated from one another can easily be produced. The contacts have a double layer comprising a vapour-deposited metal layer and an etch barrier layer. Contact separation is preferably achieved by means of non-contact local laser ablation or local etching away of the etch barrier layer and subsequent local etching away of the metal layer. No mechanical loading of the solar cell thus occurs during metallisation.

Only one vacuum deposition step is required for deposition of the metal layer and the etch barrier layer over the entire surface.

Metal contacts can be separated on a flat back side of the substrate; no surface structuring of the silicon wafer is required;

As a result of the flexible geometric configuration of the metal contacts, a low contact resistance and a low contact recombination as well as a high conductivity of the contact fingers can be achieved.

If a solderable etch barrier layer is used, this can be used simply by soldering with contact strips for connecting the solar cell to modules.

A solar cell according to the invention and a method of fabrication according to the invention have merely been described as examples by means of the above embodiments. It is noted that the previously described process steps principally relate to the part of the complete processing of a solar cell which can be used according to the invention to form base and emitter back contacts electrically insulated from one another. It is clear to persons skilled in the art familiar with the prior art that the process steps described and changes and modifications which come within the scope of the appended claims can be combined with further known process steps and in this way, various types of solar cells can be produced. For example, various further steps such as, for example, surface texturing, emitter diffusion, surface passivation, deposition of an anti-reflection layer etc. can be used to form the front side of the solar cell.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method for fabricating a solar cell comprising:
providing a semiconductor substrate with a substrate front side and a substrate back side;
forming an emitter region and a base region each on the substrate back side;
forming an electrically insulating layer on the substrate back side at least in junction regions above a region boundary at which the emitter region adjoins the base region;
depositing a metal layer at least on partial regions on the substrate back side;
depositing a dielectric etch barrier layer at least on partial regions of the metal layer, wherein the etch barrier layer is substantially resistant towards an etchant for etching metal layer;
locally removing the etch barrier layer at least in partial regions of junction regions; and
etching the metal layer, wherein the metal layer is substantially removed in the partial regions in which the etch barrier layer is locally removed.

2. The method according to claim 1, wherein the etch barrier layer is locally removed free from masking.

3. The method according to claim 1, wherein the etch barrier layer is locally removed by means of a laser.

4. The method according to claim 1, wherein the etch barrier layer is locally removed by means of a locally applied etching solution.

5. The method according to claim 1, wherein the etch barrier layer is locally removed mechanically.

6. The method according to claim 1, wherein the etch barrier layer is locally removed in a region laterally spaced apart from the region boundary.

7. The method according to claim 1, wherein at least one of the etch barrier layer and the metal layer is deposited by vapour deposition or by sputtering.

8. The method according to claim 1, wherein the etch barrier layer is locally removed in meander shaped regions.

9. The method according to claim 1, wherein the etch barrier layer is locally removed in such a manner that elongated metallisation finger regions between regions in which the etch barrier layer is removed, taper from one side edge of the solar cell towards an opposite side edge.

10. The method according to claim 1, wherein the electrically insulating layer comprises at least one of silicon oxide and silicon nitride.

11. The method according to claim 1, wherein an electrically insulating varnish layer is applied above the electrically insulating layer.
